(19) United States
(12) Patent Application Publication
(10) Pub. No.: US 2009/0001362 A1
(43) Pub. Date: Jan. 1, 2009

(54) Organic Thin Film Transistor and Manufacturing Process the Same

(75) Inventors: Satoru Toguchi, Tokyo (JP); Hiroyuki Endoh, Tokyo (JP)

Correspondence Address: YOUNG & THOMPSON, 209 Madison Street, Suite 500, ALEXANDRIA, VA, 22314, US

(73) Assignee: NEC CORPORATION, TOKYO (JP)

(21) Appl. No.: 12/279,229

(22) PCT Filed: Jan. 30, 2007
(86) PCT No.: PCT/JP2007/051444

§ 371 Date: Aug. 13, 2008

(30) Foreign Application Priority Data
Feb. 14, 2006 (JP) 2006-036475

(51) Int. Cl. H01L 51/00; H01L 51/40

(52) U.S. Cl. 257/40; 438/99; 257/E51.001

(57) ABSTRACT

Described is a SIT type organic thin film transistor in which gate electrodes are formed as a conductive layer where a plurality of wire-shaped conductive materials are arranged in such a manner that a distance to the nearest wire is 100 nm or less at any point in the space between the wires or a semiconductor portion (B) between the gate electrodes has a rectangular cross section formed by a length of shorter sides in the range of 20 nm to 200 nm and a length of longer side 2 μm or more. This provides an organic thin film transistor which can be fabricated easily at a low temperature, at a low cost, and with high-speed drive ability, a high ON/OFF ratio, and a high controllability.

### TECHNICAL FIELD

The present invention relates to an organic thin film transistor comprising an organic semiconductor material as an active layer and a manufacturing process the same.

### BACKGROUND OF THE INVENTION

Thin film transistors (TFTs) have been extensively used as a pixel switching element for a display unit such as a liquid-crystal display and an EL display. Recently, pixel array driver circuits have been increasingly formed on the same substrate by the use of TFTs. Such TFTs have been formed on a glass substrate using amorphous or polycrystal silicon. However, a CVD apparatus used for preparing such a silicon-based TFT is very expensive, leading to a problem of significant increase in a manufacturing cost associated with producing a larger-area display unit using TFTs.

Furthermore, since a process for depositing amorphous or polycrystal silicon is conducted at an extremely high temperature, there are limits to materials which can be used as a substrate; specifically, a lightweight resin substrate cannot be used.

For attempting to solve such a problem, there has been proposed a TFT using an organic semiconductor material. Vacuum deposition and application processes which are deposition processes used for forming a TFT with an organic compound has advantages that an area can be increased with a small cost and a lower process temperature can result in less limits in selecting material used as the substrate, and thus TFTs using an organic compound are expected to be practically used. Actually, TFTs using an organic compound have been extensively reported, for example, in the following references.

F. Ebisawa et al., Journal of Applied Physics, Vol. 54, p. 3255, 1983;

A. Assadi et al., Applied Physics Letter, Vol. 53, p. 195, 1988;

G. Guillaud et al., Chemical Physics Letter, Vol. 167, p. 503, 1990;

X. Peng et al., Applied Physics Letter, Vol. 57, p. 2013, 1990;

G. Horowitz et al., Synthetic Metals, Vols. 41-43, p. 1127, 1991;

S. Miyauchi et al., Synthetic Metals, Vols. 41-43, p. 1155, 1991;

H. Fuchigami et al., Applied Physics Letter, Vol. 63, p. 1372, 1993;

H. Koezuka et al., Applied Physics Letter, Vol. 62, p. 1794, 1993;

F. Garnier et al., Science, Vol. 265, p. 1684, 1994;

A. R. Brown et al., Synthetic Metals, Vol. 68, p. 65, 1994;

A. Dodabalapur et al., Science, Vol. 268, p. 270, 1995;

T. Sumimoto et al., Synthetic Metals, Vol. 86, p. 2259, 1997;

K. Kudo et al., Thin Solid Films, Vol. 331, p. 51, 1998;

K. Kudo et al., Synthetic Metals, Vols. 111-112, p. 11, 2000;

K. Kudo et al., Synthetic Metals, Vol. 102, p. 900, 1999; and

Japanese Laid-open Patent Publication No. 2003-101104.

In these documents, a conjugated polymer or a multimeric complex such as thiophene (Japanese Laid-open Patent Publication Nos. 8-228034, 8-228035, 9-232589, 10-125924 and 10-190001), a metal phthalocyanine compound (Japanese Laid-open Patent Publication No. 2000-174277) and a condensed aromatic hydrocarbon such as pentacene (Japanese Laid-open Patent Publication Nos. 5-55568 and 2001-94107) are used alone or in a mixture of other compounds, as an organic compound for an organic compound layer in a TFT.

A TFT made of such an organic compound has a disadvantage that mobility of an organic semiconductor forming an active layer is less than that of an inorganic semiconductor, leading to difficulty in high-speed drive. Furthermore, an organic semiconductor has a smaller carrier concentration than an inorganic semiconductor, which, in combination with lower mobility, causes a smaller ON current.

In a MOS type structure frequently used in a conventional inorganic semiconductor, means for solving the above problem (a lower driving speed) may include reducing a channel length to several hundred nanometers or less and increasing a gate width for complementing an insufficient ON current. Although such means may improve a driving speed, an extremely sophisticated lithography process is required for precisely forming an extremely short channel structure in a wide width, leading to a considerably higher cost in the case of application to a display device.

To solve these problems, there is proposed a static induction transistor (SIT) structure in which a channel length is a film thickness of an organic semiconductor thin film as shown in FIG. 1. In this SIT, on a supporting substrate 1 is generally formed a source electrode 2 and a drain electrode 3 and an organic semiconductor layer 8 is sandwiched between the source electrode 2 and the drain electrode 3. In this organic semiconductor layer 8, a gate electrode 4 is buried such that it does not contact both the source electrode 2 and the drain electrode 3.

In this SIT, a voltage is applied between the source and the drain electrodes and to the gate electrode, to form a channel region over the whole organic semiconductor layer 8. Thus, in this example, a channel current flows in a direction 21 from the drain electrode to the source electrode, and the thickness 22 of the organic semiconductor layer 8 is a channel length.

In such an SIT, deposition of the organic semiconductor material can be controlled in several A level, depending on the deposition conditions. Furthermore, a channel current flows through the whole surface contacting with the organic semiconductor layer 8 in the source/the drain electrodes, which allows for easily and extensively preparing a short channel structure with higher precision, leading to a larger channel current. Thus, an SIT has been developed as a useful element structure.

K. Kudo et al., Synthetic Metals, Vol. 102, p. 900, 1999 has disclosed an SIT using an organic semiconductor as an active layer, wherein a discontinuous aluminum film deposited as a thin film is used as a gate electrode.

An SIT structure element gives a large current in the ON state as described above while reduction of an OFF current is difficult, leading to an insufficient ON/OFF ratio. This is because in an SIT structure using an organic semiconductor, a region where a current can be blocked in the OFF state is limited to the vicinity of the gate electrode, which causes a continuous flow of current in the OFF state in a region distant from the gate electrode.

Japanese Laid-open Patent Publication Nos. 2001-189466 and 2005-079352 have described that as a cause of such a continuous current in the OFF state, an organic semiconductor has smaller carrier mobility and thus for obtaining an adequate ON current, a dopant concentration in the organic semiconductor must be increased and in such a case, the cause is that a depletion length of a depletion layer formed at the same voltage is decreased. However, even when an organic semiconductor layer is not doped at all, a similar phenomenon is observed, whose cause has not been clearly understood to date.

In Japanese Laid-open Patent Publication Nos. 2001-189466, 2005-079352 and 2004-023071, a channel region is formed as a through-hole between layered gate electrodes, a channel region where electric charge transfers is restricted to the inside of the through-hole formed between the gate electrodes and the size of the through-hole is adequately reduced to prevent a current from flowing in the OFF state. Specifically, an OFF current is minimized by adjusting an average radius of the through-hole to 1 to 10 μm or less. In particular, Japanese Laid-open Patent Publication No. 2001-189466 has described that most desirably, an opening of the gate electrode has an average rotation radius of 30 to 50 nm.

### SUMMARY OF THE INVENTION

Japanese Laid-open Patent Publication No. 2001-189466 has attempted to use a polymer film having a microphase separation structure as an etching mask for preparing a gate electrode in order to precisely form a channel region between layer gate electrodes. However, in this technique, it is difficult to prepare a polymer film comprising a microphase separation structure suitable for the process and this technique requires too many steps to be an inexpensive process.

When a gate electrode is etched over an organic semiconductor layer, the organic semiconductor layer is inevitably damaged, leading to difficulty in stably preparing an element exhibiting good performance. Furthermore, since a size of the through-hole formed by the microphase separation structure has a distribution, size reduction in an element size leads to considerable variation in element properties due to the size distribution. Thus, controllability is insufficient to use it for an integrated device required to have a high speed and even performance such as a driver circuit in a display.

After intense investigation for solving the above problems, we have found that a net-like conductive layer obtained by dispersing a conductive wire-shaped substance can be used as a gate electrode to inexpensively obtain an SIT structure element comprising a micropore channel.

We have also found that an element thus obtained exhibits a high ON/OFF ratio along with high-speed drive ability of the organic SIT element. Furthermore, we have found that a slit (cuboid semiconductor portion (B)) formed in a conductive layer can be used as a micropore channel in an SIT element to obtain an organic SIT element exhibiting good controllability in both ON and OFF current,

Thus, an objective of the present invention is to provide an organic thin film transistor having a higher driving speed by using a low temperature process, a larger ON current and a higher ON/OFF ratio by a convenient and inexpensive process at a low temperature. Another objective of the present invention is to provide an organic thin film transistor having a higher driving speed and exhibiting with higher controllability a larger ON current and an adequately reduced OFF current.

To solve the above problems, the present invention comprises the following aspects.

[1] An organic thin film transistor comprising a source electrode, a first organic semiconductor layer, a gate electrode layer, a second organic semiconductor layer and a drain electrode laminated in sequence, wherein the gate electrode layer comprises a gate electrode comprising a plurality of wire-shaped conductive materials and a semiconductor portion (A) made of an organic semiconductor material formed between the wire-shaped conductive materials, and

in a projection view of a distribution of the wire-shaped conductive materials in the gate electrode layer to a plane parallel to the source electrode, a distance from any point within the semiconductor portion (A) to the nearest wire-shaped conductive material is 100 nm or less.

[2] The organic thin film transistor as described in [1], wherein the surfaces of the wire-shaped conductive materials constituting the gate electrode are covered by an insulating film.

[3] A process for manufacturing the organic thin film transistor as described in [1], comprising:

forming the source electrode and the first organic semiconductor layer over the source electrode in sequence;

forming a dispersion in which the wire-shaped conductive materials are dispersed in a liquid dispersion medium;

applying the dispersion to the surface opposite to the surface in the first organic semiconductor layer on which the source electrode is formed;

removing the liquid dispersion medium by heating to form the gate electrode;

depositing an organic semiconductor material over the whole surface opposite to the side of the first organic semiconductor layer in the gate electrode, to form the semiconductor portion (A) and the second organic semiconductor layer; and

forming the drain electrode on the second organic semiconductor layer.

[4] An organic thin film transistor comprising a source electrode and a drain electrode facing each other and an intermediate layer sandwiched between the source electrode and the drain electrode,

wherein the intermediate layer comprises a gate electrode layer formed such that the intermediate layer does not contact the source electrode and the drain electrode, and an intermediate semiconductor portion made of an organic semiconductor material formed at least part of the area between the gate electrode layer and the source electrode and at least part of the area between the gate electrode layer and the drain electrode,

the gate electrode layer comprises a gate electrode and a cuboid semiconductor portion (B) penetrating a part of the gate electrode layer in its thickness direction,

the semiconductor portion (B) comprises a rectangular cross section parallel to the plane direction of the gate electrode layer, and the rectangular cross section has a length of shorter side of 20 nm or more and 200 nm or less and a length of longer side of 2 μm or more.

[5] The organic thin film transistor as described in [4], wherein the surface of the gate electrode is covered by an insulating film.

[6] A process for manufacturing the organic thin film transistor as described in [4], comprising

depositing a plurality of fibrous materials on a deposition-base such that the plurality of fibrous materials are parallel to each other, then depositing a gate electrode material over the whole surface and then removing the plurality of fibrous materials on which the gate electrode material is deposited to form the gate electrode.

[7] The process for manufacturing the organic thin film transistor as described in [4], comprising forming the gate electrode by lithography.

[8] The process for manufacturing the organic thin film transistor as described in [5], comprising:

depositing a lower insulating film material, a gate electrode material and an upper insulating film material on the source electrode and then forming a structure sequentially comprising a lower insulating film, the gate electrode and an upper insulating film by lithography; and

forming the insulating film over the surface of the gate electrode which does not contact the lower insulating film and the upper insulating film.

The term, “gate electrode layer” as used herein means a layered part comprised of a gate electrode and a organic semiconductor material part, but not consisting of a gate electrode alone. Specifically, when a gate electrode is comprised of a wire-shaped conductive material, the organic semiconductor material part becomes a semiconductor portion (A) filled in a space formed by the wire-shaped conductive material.

When a gate electrode layer is comprised of a gate electrode and a cuboid part, the cuboid part is filled with an organic semiconductor material to give a semiconductor portion (B). The gate electrode layer is formed in the intermediate layer such that it intersects the intermediate layer in a direction perpendicular to the thickness direction.

The present invention can, conveniently and at low cost, provide a vertical organic thin film transistor exhibiting a high ON/OFF ratio with higher controllability, without losing the advantages of a smaller channel length and a higher driving speed.

### BRIEF DESCRIPTION OF THE DRAWINGS

FIG. 1 is a cross-sectional view of an SIT structure element prepared using a conventional organic semiconductor.

FIG. 2 is an example of a cross-sectional view of an SIT type organic thin film transistor according to the present invention.

FIG. 3 is an example of a cross-sectional view of an SIT type organic thin film transistor according to the present invention.

FIG. 4 is an example of a cross-sectional view of an SIT type organic thin film transistor according to the present invention.

FIG. 5 is an example of a cross-sectional view of an SIT type organic thin film transistor according to the present invention.

FIG. 6 is a cross-sectional view of a region in the vicinity of an electrode in an organic thin film transistor of the present invention when it comprises a hole transport layer.

FIG. 7 is a cross-sectional view of a region in the vicinity of an electrode in an organic thin film transistor of the present invention when it comprises an electron transport layer.

FIG. 8 is a plan view of a gate electrode in the SIT type organic thin film transistor of the present invention shown in FIG. 2.

FIG. 9 is a plan view of a gate electrode in the SIT type organic thin film transistor of the present invention shown in FIG. 3.

FIG. 10 illustrates the state where a distance to the nearest wire-shaped conductive material is 100 nm or less,

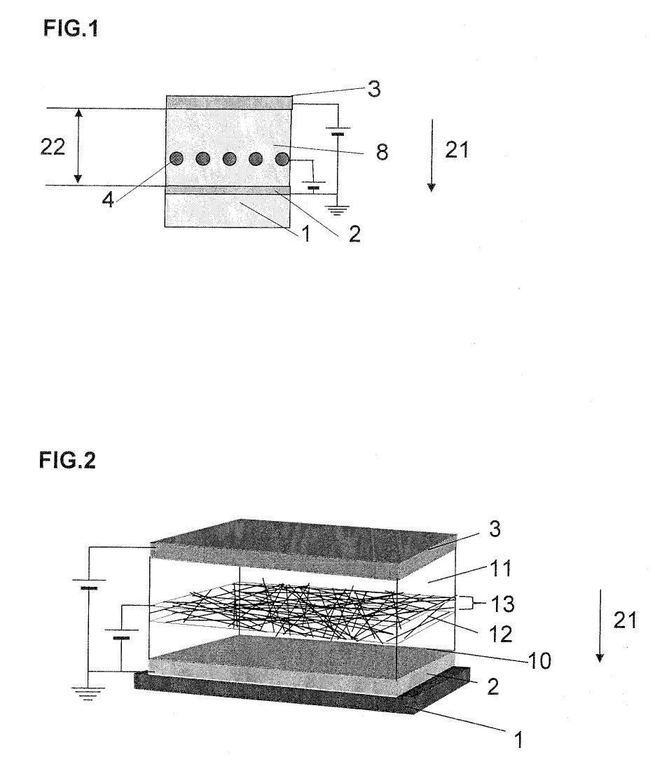

In the drawings, symbols have the following meanings; 1: supporting substrate, 2: source electrode, 3: drain electrode, 4: gate electrode, 5: lower insulating film layer, 6: upper insulating film layer, 7: lateral insulating film layer, 8: organic semiconductor layer, 9a: length of a shorter side in a rectangular cross section of a semiconductor portion (B), 9b: length of a longer side in a rectangular cross section of a semiconductor portion (B), 10: first organic semiconductor layer, 11: second organic semiconductor layer, 12: wire-shaped conductive material, 13: gate electrode layer, 14: hole transport layer, 15: electron transport layer, 23: semiconductor portion (A), 24: semiconductor portion (B), 21: direction of current flow, 31, 32, 33, 34, 35, 36 and 37: wire-shaped conductive material, 41: intermediate layer, and 42: intermediate semiconductor portion.

### DETAILED DESCRIPTION OF THE INVENTION

### Structure of an Organic Thin Film Transistor

### (1) EMBODIMENT 1

There will be described a structure of an organic thin film transistor according to the first embodiment of the present invention.

FIG. 2 shows an example of a structure of an organic thin film transistor comprising a gate electrode formed using a wire-shaped conductive material of the present invention. In this organic thin film transistor, a first organic semiconductor layer 10 is formed such that it contact a source electrode 2 formed over a supporting substrate 1. Furthermore, over the surface is disposed a gate electrode layer 13 having randomly positioned wire-shaped conductive materials 12. A second organic semiconductor layer 11 and a drain electrode 3 are further deposited in sequence over the gate electrode layer 13 to form an organic thin film transistor.

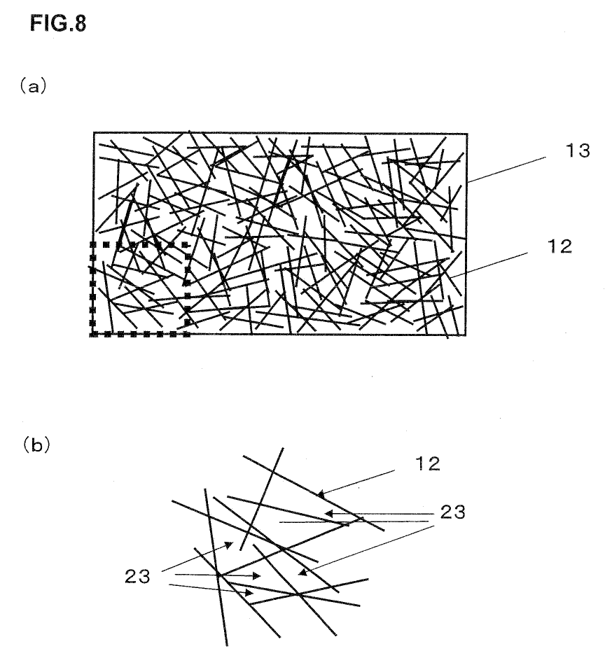

FIG. 8(a) shows a view of this gate electrode layer from above. FIG. 8b is an enlarged view of the region surrounded by a dot line of a gate electrode layer of FIG. 8(a). Individual wire-shaped conductive materials 12 in the gate electrode layer 13 contact one or a plurality of adjacent wire-shaped conductive materials 12 to form a space. In this embodiment, since individual wire-shaped conductive materials mutually contact, applying a voltage to some wire-shaped conductive materials can result in voltage application to all the wire-shaped conductive materials. Thus, this wire-shaped conductive material assembly corresponds to a gate electrode.

Spaces between these wire-shaped conductive materials 12 are entirely filled with an organic semiconductor material to form a semiconductor portion (A) 23. Furthermore, in a projection view of a distribution of the wire-shaped conductive materials in the gate electrode layer to a plane parallel to the source electrode, a distance from any point within the part corresponding to the semiconductor portion (A) to the nearest wire-shaped conductive material is 100 nm or less. Specifically, a circle with a radius of 100 nm having a center within the space (the part corresponding to the semiconductor portion (A)) has a structure where a wire-shaped conductive material is always contained within the circle or on the circumference.

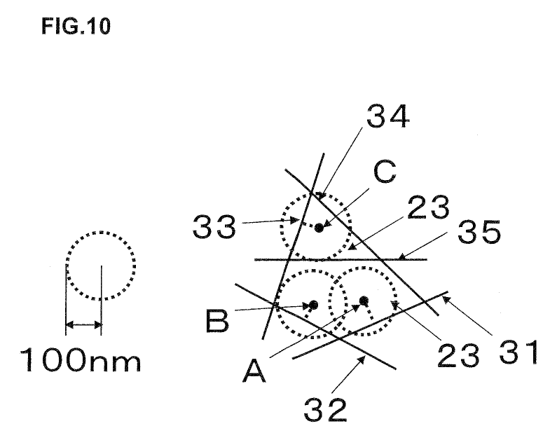

More specifically, whether “a distance from any point within the semiconductor portion (A) to the nearest wire-shaped conductive material is 100 nm or less” or not can be determined as follows. First, a projection view of a distribution of the wire-shaped conductive materials in the gate electrode layer to a plane parallel to the source electrode is obtained. FIG. 10 is an example of such a projection view. In this projection view, a distance from any point in the semiconductor portion (A) 23 to the nearest wire-shaped conductive material (the shortest distance to the nearest wire-shaped conductive material) must be 100 nm or less.

For example, assuming that point A in the semiconductor portion (A) 23 is a starting point, the nearest wire-shaped conductive material to point A is 31. In the present invention, the shortest distance from point A to the wire-shaped conductive material 31 (the dot line in this figure) is 100 nm or less. The shortest distances from points B and C to the wire-shaped conductive materials 32 and 33 (the dot lines in this figure) are, likewise, 100 nm or less. Whether the nearest wire-shaped conductive materials are within 100 nm or less from points A to C in the semiconductor portion (A) 23 as described above can be confirmed by specifically drawing circles with a radius of 100 nm centering the individual points (the circles drawn by a dot line in this figure) and then determining the existence of the wire-shaped conductive materials within the circles or on the circumferences of the circles.

Although the shortest distances from three points to the wire-shaped conductive materials have been described in FIG. 10, the shortest distance from any arbitrary point (all points) in a part (space) corresponding to the semiconductor portion (A) to the nearest wire-shaped conductive material is 100 nm or less in the present invention. In other words, this invention is characterized in that irrespective of selection of any point in the semiconductor portion (A), the shortest distance to the nearest wire-shaped conductive material is 100 nm or less.

A specific method for determining whether “a shortest distance from any point within a part corresponding to the semiconductor portion (A) to the wire-shaped conductive material is 100 nm or less” or not will be detailed in Examples.

In the organic thin film transistor of this embodiment comprising the above structure, particularly the structure in which the shortest distance from a given point in the semiconductor portion (A) to the nearest wire-shaped conductive material is 100 nm or less, in ON state, a channel region is effectively formed in the first organic semiconductor layer 10, the second organic semiconductor layer 11 and the semiconductor portion (A) 23, resulting in a large ON current. Furthermore, a space between the wire-shaped conductive materials 12 is small enough to effectively reduce a channel current in OFF state.

The wire-shaped conductive materials 12 may be disposed either randomly or in a manner that to some extent they are oriented to a given direction. However, even when they are disposed with an orientation to a given direction to some extent, any adjacent wire-shaped conductive materials 12 contacts each other (individual wire-shaped conductive materials 12 are not entirely parallel), and a semiconductor portion (A) is formed between these wire-shaped conductive materials and a distance from any point in the semiconductor portion (A) to the nearest wire-shaped conductive material must be 100 nm or less.

Thus, whether within the gate electrode layer 13, the wire-shaped conductive materials 12 are disposed randomly or with an orientation to some extent can be selected by controlling a method for forming the gate electrode and its conditions. For example, a structure where the wire-shaped conductive materials 12 are randomly disposed can be formed by preparing a homogeneous dispersion of the wire-shaped conductive materials in a liquid dispersion medium, applying the dispersion onto a first organic semiconductor layer 10 on a supporting substrate and removing the liquid dispersion medium.

Such a manufacturing process can eliminate the necessity of a difficult step, for example, using a conventional microphase separation structure as an etching mask and of an etching step giving damage to other parts. Furthermore, a gate electrode layer comprising an adequately small and precisely controlled channel region can be conveniently and inexpensively formed.

The wire-shaped conductive material may be straight or curved. Alternatively, it may be bent. There are no particular restriction to the shape of the semiconductor portion (A) which is formed between the wire-shaped conductive materials, including a circle, a curved shape, a quadrangle and a polygon.

The surface of the gate electrode (the wire-shaped conductive material) is preferably covered by an insulating film. In the organic thin film transistor of the present invention, there is the semiconductor portion (A) between the wire-shaped conductive materials covered by an insulating film even in such a case. In addition, the shortest distance from a given point in the semiconductor portion (A) to the nearest wire-shaped conductive material is 100 nm or less, Thus, a channel region is effectively formed within this semiconductor portion (A), resulting in a large ON current. Furthermore, a space between the wire-shaped conductive materials can be more reduced to more effectively reduce a channel current in OFF state.

A thickness of the gate electrode layer (a length in a direction from the source electrode to the drain electrode; a length in the direction of the arrow 21 in FIG. 2) is preferably 20 to 100 nm. If the thickness is less than 20 nm, an electric resistance as the whole gate electrode may be increased. If the thickness is more than 100 nm, a channel length is increased, which may lead to reduction in a driving speed of the organic thin film transistor.

The organic semiconductor materials constituting the first organic semiconductor layer 10, the second organic semiconductor layer 11 and the semiconductor portion (A) 23 in the gate electrode layer may be the same or different. Preferably, in the light of controllability and facility in production of the element properties of the organic thin film transistor, all of the organic semiconductor materials constituting the first organic semiconductor layer 10, the second organic semiconductor layer 11 and the semiconductor portion (A) 23 in the gate electrode layer are the same.

Therefore, according to the present invention, an element allowing high-speed drive, adequate reduction of an OFF current and a high ON/OFF ratio can be obtained easily in an SIT type organic thin film transistor using, as an active layer, an organic semiconductor material which can be prepared at a low temperature.

### (2) EMBODIMENT 2

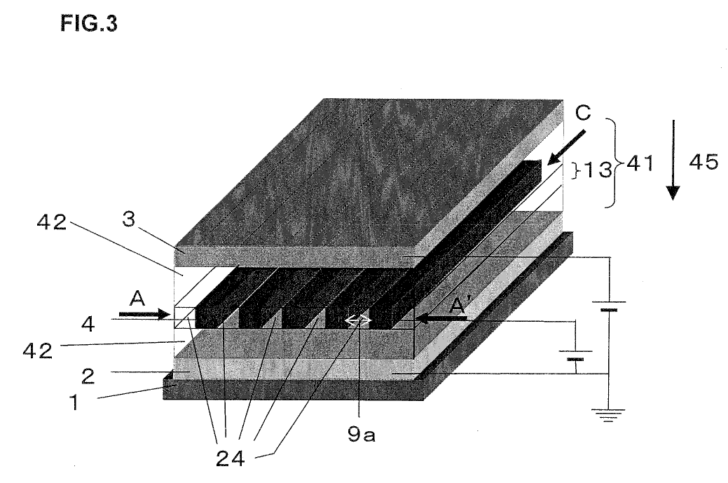

FIG. 3 shows an example of a structure of an organic thin film transistor according to the second embodiment of the present invention. In this organic thin film transistor, a source electrode 2 and a drain electrode 3 facing the source electrode 2 are formed on a supporting substrate 1 and an intermediate layer 41 is formed between a source electrode 2 and a drain electrode 3. This intermediate layer 41 comprises a gate electrode layer 13 formed such that it does not contact the source electrode 2 or the drain electrode 3, and an intermediate semiconductor portion 42 composed of an organic semiconductor material at least in part of the region between the gate electrode layer 13 and the source electrode 2 and at least in part of the region between the gate electrode layer 13 and the drain electrode 3. In the organic thin film transistor shown in FIG. 3, all the region between the gate electrode layer 13 and the source/drain electrode is the intermediate semiconductor portion 42.

This gate electrode layer 13 comprises at least a gate electrode 4, and a cuboid semiconductor portion (B) 24 penetrating a part of the gate electrode layer in its thickness direction 45. The cuboid semiconductor portion (B) 24 is filled with an organic semiconductor material. Since this semiconductor portion (B) is a cuboid, a cross section (a cross section perpendicular to a thickness direction 45 of the gate electrode layer; in FIG. 3, a cross section over the plane ABC (a plane passing through points ABC)) parallel to the plane direction of the gate electrode layer (a plane direction of the source/the drain electrodes; a plane direction of the first organic semiconductor layer and the second organic semiconductor layer) is a rectangular cross section.

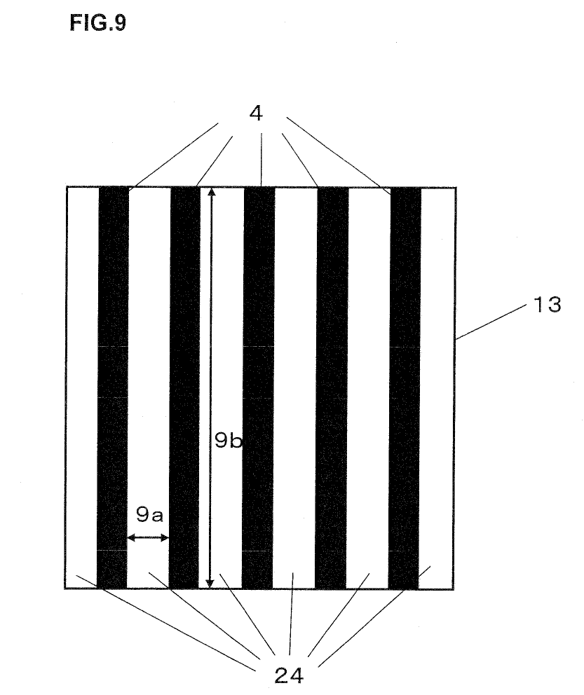

FIG. 9 is a plan view of the gate electrode layer shown in FIG. 3. In the gate electrode layer of FIG. 9, there are five gate electrodes 4 in the gate electrode layer 13. Each gate electrode 4 is connected to a power supply (not shown) for applying a voltage (in FIG. 3, one gate electrode 4 is schematically connected to a power supply).

A semiconductor portion (B) 24 is formed between the gate electrodes 4 and optionally at the end of the gate electrode layer 13. Each semiconductor portion (B) 24 is filled with an organic semiconductor material. A cross section of this semiconductor portion (B) parallel to the plane direction of the gate electrode layer (the cross section shown in FIG. 9) is rectangular.

In the organic thin film transistor of this embodiment, the shorter side of this rectangular cross section must have a length (9a in FIGS. 3 and 9) of 20 nm or more and 200 nm or less and the longer side must have a length (9b in FIGS. 3 and 9) of 2 μm or more. The longer and the shorter sides in each semiconductor portion (B) may be the same or different in their length.

For obtaining an adequately reduced OFF current, the semiconductor portion (B) must have a length of shorter side of 200 nm or less, but if a length of shorter side is too small, size variation of a patterning edge may more significantly affect controllability in current modulation. The length of shorter side must be, therefore, 20 nm or more at the same time.

In the edge of the semiconductor portion (B) 24, homogeneity of the channel region tends to be deteriorated and such disturbance in homogeneity of the channel region becomes more significant as a ratio of the width of the edge (the length of shorter side) 9a and a length of longer side of 9b, that is, 9a/9b, increases. Thus, for reducing this ratio 9a/9b, a length of longer side of each semiconductor portion (B) must be 2 μm or more.

When the gate electrode has a cuboid shape, its width (a length of shorter side in the rectangular cross section parallel to the plane direction of the source/the drain electrodes; a length of the shorter side in the rectangular cross section perpendicular to the thickness direction of the gate electrode layer) is preferably 20 to 200 nm. If the width is less than 20 nm, an electric resistance as the whole gate electrode may be increased. On the other hand, if the width is more than 200 nm, a parasitic capacity of the gate electrode is increased, which may lead to reduction in a driving speed of the organic thin film transistor. A length of the gate electrode (a length of the longer side in the rectangular cross section parallel to the plane direction of the source/the drain electrodes; a length of the longer side in the rectangular cross section perpendicular to the thickness direction of the gate electrode layer) is preferably equal to the length of longer side in the rectangular cross section in the semiconductor portion (B).

As described above, since the semiconductor portion (B) has the lengths of shorter side and the longer side within a certain range, the organic thin film transistor of this embodiment can effectively form a channel region in the semiconductor portion (B) in ON state. In OFF state, a channel current can be effectively eliminated. In the gate electrode layer 13, the gate electrode and the semiconductor portion (B) may be regularly arranged in a given direction as shown in FIG. 3 or not.

A shape of the gate electrode 13 is not limited to a cuboid as shown in FIG. 3, but there are no particular restrictions as long as there is a cuboid semiconductor portion (B) in the gate electrode layer 13. Furthermore, it is just necessary that the gate electrode layer 13 contains at least one gate electrode, and there may be contained one or more gate electrodes.

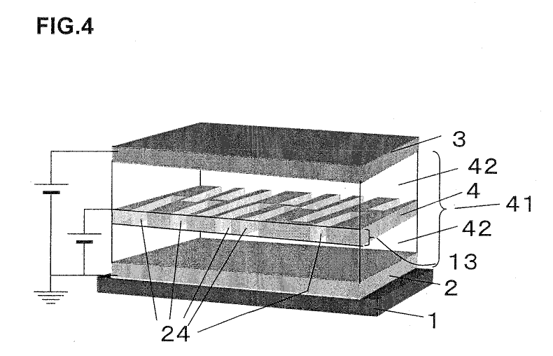

When the semiconductor portion (B) does not have a regular arrangement, for example, the gate electrode 4 may have a slit-containing shape, whose space may be filled with an organic semiconductor material to form a cuboid semiconductor portion (B) as shown in FIG. 4.

### (3) EMBODIMENT 3

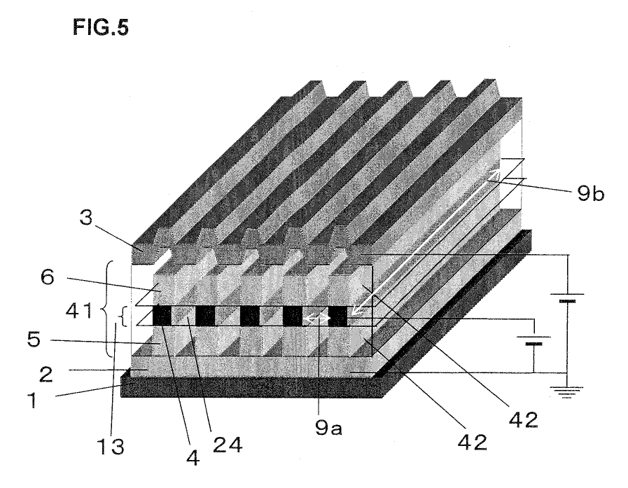

FIG. 5 shows an example of a structure of an organic thin film transistor according to the third embodiment of the present invention. This embodiment is a modification of Embodiment 2 and is different from Embodiment 2 in that an insulating film is formed covering a gate electrode surface in the second organic thin film transistor.

As in the second embodiment, this organic thin film transistor comprises a source electrode 2, an intermediate layer 41 and a drain electrode 3 over a supporting substrate 1, but is different in that the surface of a gate electrode in the gate electrode layer 13 present in the intermediate layer 41 is covered by an insulating film. There are no particular restrictions to a thickness of the insulating film or a covering pattern of the gate electrode surface as long as the effects of the present invention are achieved.

In an organic thin film transistor of the present invention, there is the semiconductor portion (B) between the gate electrodes covered by the insulating layer, even in such a case. Furthermore, a length of the shorter side of the rectangular cross section in the semiconductor portion (B) is 20 nm or more and 200 nm or less, while a length of the longer side is 2 μm or more. Thus, patterning can be stably patterned and in OFF state, a channel current can be more effectively reduced.

More specifically, a cuboid first insulating film layer (a lower insulating film layer) 5 is formed over the source electrode 2 for supporting a gate electrode 4 and a cuboid gate electrode 4 is disposed over the cuboid first insulating film layer. Then, a cuboid second insulating film layer (an upper insulating film layer) 6 is formed over the surface while a lateral insulating film layer is formed on the lateral side of the gate electrode 4 (although FIG. 5 does not show the lateral insulating film layer). In the gate electrode layer 13, the semiconductor portion (B) 24 is formed between the gate electrodes 4 covered by the lateral insulating film layer. There are no particular restrictions to a thickness or shape of the upper insulating film layer 6, the lower insulating film layer 5 or the lateral insulating film layer 7 as long as the properties of the organic thin film transistor of the present invention are not deteriorated. The part in the intermediate layer 41 other than the gate electrode layer 13, the upper insulating film layer 6 and the lower insulating film layer 5 is the intermediate semiconductor portion 42 made of an organic semiconductor material (in the intermediate layer 41, a part of the region between the gate electrode layer 13 and the source/the drain electrodes is an intermediate semiconductor portion 42).

In any of the above Embodiments 2 and 3, the semiconductor portion (B) is a cuboid. Therefore, a homogeneous channel region is formed in a depth direction (a longer side direction) in the semiconductor portion, unlike an amorphous structure such as a separation structure formed using a polymer film comprising a microphase separation structure as an etching mask and a metal discontinuous film. Thus, modulation effect of the gate electrode 4 to a current flowing the channel region is homogeneous. As a result, both ON and OFF currents can be modulated with higher controllability as a whole.

The above semiconductor portion can be patterned by, besides common lithography, aligning in an orientation a fibrous material on a first organic semiconductor layer formed on a source electrode, using it as a shadow mask to deposit a gate electrode material and then removing the fibrous material to form a gate electrode (a shadow mask method).

The fibrous material used in this method has a rectangular shape in a projection plane. Thus, after depositing a gate electrode material, this fibrous material is removed to form an opening having a rectangular shape in a projection plane in a part where the fibrous material has remained, in the region on the first organic semiconductor layer. Then, in a later step, this part is filled with an organic semiconductor material to form a semiconductor portion (B) having a rectangular cross section. Therefore, the size of the projection plane of this fibrous material can be controlled to control the lengths of the shorter and the longer sides of the semiconductor portion (B) to a given range. In the region without the fibrous material, the gate electrode material remains over the first organic semiconductor layer, and as such becomes a gate electrode.

As the width of the semiconductor portion (B) is reduced, lithographic patterning requires a higher-level and higher-cost process, and therefore, a shadow-mask process using a fibrous material is effective as a low-cost process.

Thus, the present invention can easily prepare an element allowing a high-speed drive, exhibiting good controllability of ON and OFF currents and having a higher ON/OFF ratio in an SIT type organic thin film transistor using an organic semiconductor material which can be prepared at a low temperature, as an active layer.

Furthermore, as a modification of the second embodiment, an insulating film layer may be formed between the gate electrode layer and the intermediate layer or between the gate electrode and the source/the drain electrodes. In particular, when forming an insulating film layer between the gate electrode layer and the intermediate layer, a gate leak current can be adequately reduced in a wide gate bias region, and thus such a structure is suitable for an organic thin film transistor having a larger voltage/current modulation range.

### Materials for an Organic Thin Film Transistor

The following materials can be used for an organic thin film transistor of the present invention.

### Source and Drain Electrodes

There are no particular restrictions to materials for a source and a drain electrodes of the present invention as long as they have adequate conductivity, but an electrode acting as a charge-injection electrode preferably has excellent charge-injection properties to an organic semiconductor.

Examples of such a material for an electrode include, but not limited to, metals and alloys such as an indium oxide-tin alloy (hereinafter, referred to as “ITO”), tin oxide (NESA), gold, silver, platinum, copper, indium, aluminum, magnesium, a magnesium-indium alloy, a magnesium-aluminum alloy, an aluminum-lithium alloy, an aluminum-scandium-lithium alloy and a magnesium-silver alloy and their oxides and organic materials such as conductive polymers.

### Gate Electrode

A material which can be used for a gate electrode according to the second embodiment of the present invention depends on whether an insulating film layer is formed between the gate electrode layer and the intermediate layer or not. When forming an insulating film layer between the gate electrode layer and the intermediate layer, the material includes those used for the above source/drain electrodes and there are no particular restrictions to the material as long as it exhibits adequate conductivity.

However, when an insulating film layer is not formed between the gate electrode layer and the intermediate layer, there must be a sufficiently large Schoftky charge-injection barrier between the gate electrode and the intermediate layer for adequately reducing a leak current from the gate electrode. Thus, a material having a suitable work function difference or ion-potential difference to the materials used for the intermediate semiconductor portion and the semiconductor portion (B) is selected.

Examples of a wire-shaped conductive material constituting the above gate electrode of Embodiment 1 include, but not limited to, carbon nanotube, a doped semiconductor nanowire and a metal nanowire. There are no particular restrictions to a diameter or length of the wire-shaped conductive material, but for meeting the condition that a distance from any point in a space formed to the nearest wire is 100 nm or less, the diameter of the wire-shaped conductive material is preferably less than 100 nm.

### Liquid Dispersion Medium

Any liquid may be used as a liquid dispersion medium which disperses the wire-shaped conductive material during forming the above gate electrode layer of Embodiment 1, as long as it can disperse the wire-shaped conductive material and does not deteriorate the wire-shaped conductive material. Examples of such a liquid include, but not limited to, water and common organic solvents such as alcohols, ethers, esters, alkylamides, aliphatic hydrocarbons and aromatic compounds.

A dispersion method may be used by any procedure used for a dispersion step of, for example, a common pigment, including kneading methods such as stirring and milling, and ultrasonic irradiation. During the process, an appropriate surfactant may be added for accelerating and/or maintaining a dispersed state.

A method for applying a dispersion to the first organic semiconductor layer can be a film forming method where a dispersion prepared by dispersing a wire-shaped conductive material in the above liquid dispersion medium is applied by spin coating or blade coating, or can be a printing method such as ink-jet printing. Here, the size of a space formed between the wire-shaped conductive materials depends on a concentration of the wire-shaped conductive material in the dispersion and a rate of removing the liquid dispersion medium. When an desired adequately small space cannot be obtained by a single application step, a space with a desired size can be obtained by making some adjustment including increase in a concentration of the wire-shaped conductive material in the dispersion, increase in a thickness of the applied film, and repeated application and drying of the dispersion.

### Insulating Film Layer

In Embodiment 3, as examples of materials for the insulating film layer (the upper insulating film layer, the lower insulating film layer and the lateral insulating film layer) covering the gate electrode, the insulating film layer formed between the gate electrode layer and the intermediate layer, or the insulating film layers formed between the gate electrode and the source electrode and between the gate electrode and the drain electrode, inorganic insulating materials such as SiO₂, SiNₓ and alumina and insulating polymers can be illustrated and but the materials is not limited to those.

### Organic Semiconductor Layer

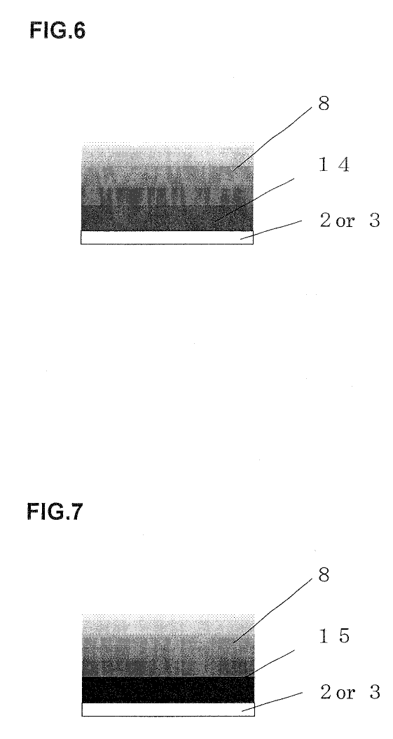

An organic semiconductor layer (a first organic semiconductor layer and a second organic semiconductor layer) and an intermediate semiconductor portion in the present invention contains a layer or part made of at least one organic semiconductor material. If necessary, the intermediate layer and the organic semiconductor layer may be constituted by a laminate structure of an organic semiconductor layer and a layer assisting hole or electron injection, and a laminate structure of an intermediate semiconductor portion and a layer assisting hole or electron injection (a hole-injection layer and an electron-injection layer), respectively. FIGS. 6 and 7 show a structure around such a source electrode or drain electrode. As shown in FIGS. 6 and 7, each of the hole-injection layer and the electron-injection layer is in contact with each electrode and disposed in a way that it is sandwiched by each electrode and the organic semiconductor layer or each electrode and the intermediate semiconductor portion.

Materials for the organic semiconductor layer and the intermediate semiconductor portion of the present invention may be any material commonly used for an organic thin film transistor. Examples of a low-molecular material include, but not limited to, metal complexes or dinuclear metal complexes comprising a 8-quinolinol derivative as at least one ligand, non-metallized or metal-complexed phthalocyanine derivatives, perylene tetracarboxylic diimide derivatives, quinacridone derivatives, polycyclic quinones such as anthraquinone derivatives, fullerene derivatives, semiconductive carbon nanotubes, dimeric compounds of a diphenylvinylarylene derivative via a linking group, 9,9′-spirobifluorene derivatives, and nitrogen-containing heterocyclic compound derivatives such as oxadiazole derivatives and triazole derivatives, triphenylmethane derivatives, triphenylamine derivatives such as N,N′-diphenyl-N,N-bis(1-naphthyl)-1,1-biphenyl)-4,4-diamine (hereinafter, referred to as “NPD”) and multimers of such a compound via a linking group, silole derivatives, 9,9-diphenylfluorene derivatives, a star burst amine compound represented by general formula [1], and halogenated derivatives of aromatic hydrocarbon compounds having 14 to 34 carbon atoms such as anthracene, perylene, pentacene and pyrene.

wherein Ar¹ to Ar² are independently substituted or unsubstituted aromatic hydrocarbon having 6 to 20 carbon atoms or substituted or unsubstituted aromatic heterocycle having 6 to 20 carbon atoms, where substituents in Ar¹ to Ar² may be combined to form a ring; X is a mono- to tetra-valent group of substituted or unsubstituted aromatic hydrocarbon groups having 6 to 34 carbon atoms or a mono- to tetra-valent group of triphenylamine derivative skeletons; and n represents an integer of 1 to 4.

Herein, X is a mono- to tetra-valent group of substituted or unsubstituted aromatic hydrocarbon groups having 6 to 34 carbon atoms. Examples of an unsubstituted aromatic hydrocarbon having 6 to 34 carbon atoms include benzene, naphthalene, anthracene, biphenylene, fluorene, phenanthrene, naphthacene, triphenylene, pyrene, dibenzo[cd,jk]pyrene, perylene, benzo[a]peryiene, dibenzo[a,j]perylene, dibenzo[a,o]perylene, pentacene, tetrabenzo[de,hi,op,st]pentacene, tetraphenylene, Terrylene, bisantrene and 9,9′-spirobifluorene.

Examples of a substituent in these aromatic hydrocarbons include halogen, hydroxyl, substituted or unsubstituted amino, nitro, cyano, substituted or unsubstituted alkyl, substituted or unsubstituted alkenyl, substituted or unsubstituted cycloalkyl, substituted or unsubstituted alkoxy, substituted or unsubstituted aromatic hydrocarbon, substituted or unsubstituted aromatic heterocycle, substituted or unsubstituted aralkyl, substituted or unsubstituted aryloxy, substituted or unsubstituted alkoxycarbonyl and carboxyl.

Examples of a metal atom used in the above metal complexes include aluminum, berylium, bismuth, cadmium, cerium, cobalt, copper, iron, gallium, germanium, mercury, indium, lanthanum, magnesium, molybdenum, niobium, antimony, scandium, tin, tantalum, thorium, titanium, uranium, tungsten, zirconium, vanadium, zinc, titanium oxide, sodium, potassium, lithium and oxides of these metals.

Examples of a polymer material include, but not limited to, heterocyclic conjugated polymers such as polythiophene derivatives and polypyrrole derivatives; polyphenylene derivatives such as polyparaphenylene; conjugated polymers such as aromatic hydrocarbon conjugated polymers including polyphenylene vinylene derivatives; and pendant type polymers where the low-molecule material skeleton described above as a side chain is attached to a main chain such as polyethylene, polyether, polyeste and polyamide via a linking group comprising an ester or amide bond or directly single bond.

### Hole-Injection Layer

There are no particular restrictions to a material for a hole-injection layer of the present invention and any compound may be used as long as it is commonly used as a hole-injection material. Examples include phthalocyanine derivatives such as copper phthalocyanine, bis(di(p-tolyl)aminophenyl)-1,1-cyclohexane, N,N,N′,N′-tetraamino-4,4′-diaminobiphenyl, triphenyidiamines such as NPD described above and starburst type molecules such as tris(4-(N,N-di-m-tolylamino)phenyl)amine.

### Electron-Injection Layer

There are no particular restrictions to a material for the electron-injection layer of the present invention and any compound may be used as long as it is commonly used as an electron-injection material. Examples include oxadiazole derivative such as 2-(4-biphenylyl)-5-(4-t-butylphenyl)-1,3,4-oxadiazole and OXD-7; triazole derivatives such as 3-(4-biphenylyl)-5-(4-t-butylphenyl)-1,2,4-triazole and quinolinol metal complexes such as a tris-8-quinolinol aluminum complex.

### Process for Manufacturing an Organic Thin Film Transistor

### (1) Process for Forming a Gate Electrode Layer in Embodiment 1

A gate electrode layer according to Embodiment 1 of the present invention can be formed by dispersing a material to be a gate electrode (a wire-shaped conductive material) in a liquid dispersion medium to form a dispersion, applying this dispersion on a preformed support-source electrode-first organic semiconductor layer and then evaporating the liquid dispersion medium.

Any procedure may be used for a dispersion method as long as it is used as a common dispersion step of pigment, for example, including kneading methods such as stirring and milling, and ultrasonic irradiation. During the process, an appropriate surfactant may be added for accelerating and/or maintaining a dispersed state.

A method for applying a dispersion can be a method where a dispersion prepared by dispersing a wire-shaped conductive material in the above liquid dispersion medium is applied by a film forming method such as spin coating or blade coating, or can be a printing method such as inkjet printing. Here, the size of a space formed between the wire-shaped conductive materials depends on a concentration of the wire-shaped conductive material in the dispersion and a rate of removing the liquid dispersion medium. When a desired adequately small space cannot be obtained by a single application step, a space with a desired size can be obtained by making some adjustment including increase in a concentration of the wire-shaped conductive material in the dispersion, increase in a thickness of the applied film and repeated application and drying of the dispersion.

### (2) Process for Forming a Gate Electrode Layer in Embodiments 2 and 3

A gate electrode layer according to Embodiments 2 and 3 of the present invention can be formed by lithography. The lithographic method used in the present invention may be, besides a common photolithography using a photomask, any method allowing for forming a strip pattern with a width of 20 nm or more and 200 nm or less such as electron-beam direct lithography.

Alternatively, a gate electrode layer according to Embodiments 2 and 3 of the present invention may be formed using a shadow mask method. This shadow mask method is a process where a plurality of fibrous materials are deposited on a deposition base such that they are mutually parallel, a gate electrode material is deposited over the whole surface and then the plurality of fibrous materials on which the gate electrode material has been deposited are removed to form a gate electrode. Here, the deposition base is an intermediate semiconductor portion or insulating film (the latter is when an insulating film is formed between the intermediate semiconductor portion and the gate electrode layer). As described above, since a semiconductor portion (B) is formed in the part of the fibrous materials used as a shadow mask in a shadow mask method, the shape and the size of the fibrous materials are determinant factors to the shape and the size of the semiconductor portion (B). Thus, any fibrous material may be used as long as the fibrous material has a diameter of 20 nm or more and 200 nm or less and a length of 2 μm or more and is adequately tolerant to a dry process such as vacuum deposition and sputtering and a wet process such as spray coating and blade coating during forming the gate electrode.

Examples include, but not limited to, a carbon nanowire, a metal nanowire and a semiconductor nanowire and furthermore a rod-like resin. A method for orienting and depositing these fibrous materials to a parallel direction is the method where a dispersion of these materials is directly applied to a deposition surface in one direction by a coating method such as dip coating, spray coating and blade coating, first applying the fibrous materials on a base comprising an orienting groove to deposit the fibrous materials in one orientation and then transfer them, or transferring an LB film made from the fibrous materials to a base, or alternatively growing a nanowire in an orientation in an electric field, but a process used is not limited to these as long as it can align the wire-shaped materials in a desired orientation.

### Process for Forming a Source/a Drain Electrodes and an Insulating Film Layer

There are no particular restrictions to a process for forming each electrode (a source/a drain electrodes) and an insulating film layer in an organic thin film transistor of the present invention. In addition to well-known vacuum deposition, spin coating, sputtering and CVD, a common film forming method such as application or application-sintering and anodic oxidation can be employed. In the case of a process applied after forming an organic semiconductor layer (a first organic semiconductor layer or a second organic semiconductor layer), it is necessary to select a method which does not damage the interface and the inside of the organic semiconductor thin film and does not deteriorate transistor properties.

### Process for Forming an Organic Semiconductor Layer

There are no particular restrictions to a process for forming an organic semiconductor layer containing an organic semiconductor compound used in an organic thin film transistor of the present invention (a first organic semiconductor layer, a second organic semiconductor layer, a semiconductor portion (A), a semiconductor portion (B) and an intermediate semiconductor portion). Well-known common processes for forming an organic thin film can be employed. For example, the organic semiconductor layer can be formed by wet processes such as dipping, spin coating, casting, bar coating, roll coating and inkjet printing of a solution in a solvent, and vacuum deposition and molecular-beam deposition (MBE process).

An etching method in the manufacturing process of the present invention is appropriately selected, depending on an electrode material and an insulating film material used. For example, when a silicon-containing insulating material such as SiO₂ is etched, a method which can be used include, but not limited to, wet etching using hydrofluoric acid and dry etching using a fluorine-containing gas.

There are no particular restrictions to a film thickness of an organic semiconductor layer of an organic thin film transistor of the present invention, but in general a too thin film tends to cause defects such as pin holes while a too thick film may lead to an excessively long channel, resulting in loss of the advantages of a vertical organic thin film transistor, and therefore, it is preferably within a range of several ten nanometers to 1 μm.

### EXAMPLES

### Example 1

There will be described a process for preparing an organic thin film transistor according to Embodiment 1. First, ITO was deposited on a glass substrate to 100 nm by sputtering, as a source electrode. Then, NPD was deposited in a limited region containing a channel region over ITO to 100 nm by vacuum deposition via a metal mask, as a lower organic semiconductor layer.

On the lower organic semiconductor layer (the first organic semiconductor layer) thus formed was applied a dispersion containing a metallic carbon nanotube as a wire-shaped conductive material, a substituted benzenesulfonic acid sodium salt as a surfactant and water as a liquid dispersion medium by spin coating and then the dispersion was dried to remove water.

Then, gold was deposited over the region free from ITO and an organic semiconductor layer to a film thickness of 100 nm by vacuum deposition as an extraction electrode such that it was connected to the metal carbon nanotube layer. Next, the product was washed by flowing water for 30 min to remove the surfactant.

While rotating the substrate, NPD was deposited over the same region as the lower organic semiconductor layer on the carbon nanotube gate electrode thus formed to a film thickness of 250 nm by vacuum deposition in a direction tilted at 30 degrees to the substrate normal line. Here, a space between the carbon nanotubes was filled with NPD to form a semiconductor portion (A) while an upper organic semiconductor layer (the second organic semiconductor layer) was formed. Furthermore, aluminum as a drain electrode was deposited by vacuum deposition to 100 nm to prepare an organic thin film transistor.

As samples, twenty organic thin film transistors were prepared by described above. For these twenty samples, a dispersion film in the carbon nanotube was observed under magnification by an atomic force microscope (AFM) (Pacific Nanotechnology, Inc.) before forming the second organic semiconductor layer. It was analyzed by visual observation for determining the presence of spaces between the wire-shaped conductive materials in which there can exist a circle with a radius of 100 nm not containing, whether entirely or partly, the wire-shaped conductive material at all on or within circumference of the circle.

When there is a space in which there exists a circle with a radius of 100 nm not containing the wire-shaped conductive material on or within its circumference, it can be determined that within the space, there exists a point having a distance from the nearest wire-shaped conductive material of more than 100 nm. On the other hand, when there is not a space having such a circle with a radius of 100 nm, it can be determined that at any point in the space, a distance from the nearest wire-shaped conductive material is 100 nm or less. In spaces surrounded and formed by carbon nanotubes in the carbon nanotube dispersion film obtained in this example, there can not exist a circle with a radius of 100 nm not containing the wire-shaped conductive material on or within circumference of the circle. Thus, it was confirmed that at any point within each space, the shortest distance to the nearest carbon nanotube was 100 nm or less.

Thus, twenty organic thin film transistors were prepared and were measured for their transistor properties by a semiconductor parameter analyzer, and a cutoff frequency fc was 1 kHz and an ON/OFF ratio (a current ratio between a source and a drain when applying a source-drain bias of −4 V under the conditions of ON state: gate voltage=−5 V and OFF state: gate voltage=+5 V; the same shall apply hereinafter) was 10³. It was thus confirmed that employing the configuration of the present invention, an organic thin film transistor having a high ON/OFF ratio was manufactured by a convenient process.

### Comparative Example 1

An organic thin film transistor was prepared as described in Example 1, except that a dispersion of the metallic carbon nanotube was used in a one-fifth concentration. AFM observation of a carbon nanotube dispersion film before forming a second organic semiconductor layer as described in Example 1 indicated that there were many spaces between the carbon nanotubes in which there may exist a circle with a radius of 150 nm not containing the carbon nanotube at all on or within its circumference. Twenty organic thin film transistors thus obtained were evaluated, and a cutoff frequency was 900 Hz and an ON/OFF ratio was 12. Thus, the organic thin film transistor prepared in this comparative example had a low ON/OFF ratio.

### Example 2

There will be described a process for manufacturing an organic thin film transistor according to Embodiment 3. ITO as a source electrode was deposited on a glass substrate to 100 nm by sputtering. Then, SiO₂ as a lower insulating film layer was deposited over ITO to a film thickness of 60 nm by sputtering, and then aluminum as a gate electrode material was deposited to a film thickness of 30 nm by vacuum deposition. Subsequently, SiO₂ as an upper insulating film layer was deposited to a film thickness of 30 nm by sputtering.

A resist film was deposited over the multilayer film thus formed to a film thickness of 400 nm by spin coating using an electron-beam drawing resist ZEP520-22 (Nihon Zeon Corporation). Then, an antistatic agent Espacer 300Z (Showa Denko K. K.) was deposited as an antistatic film by spin coating. Next, a 600 μm×600 μm area was exposed and developed in a comb-tooth shape with a line width of 100 nm and an interval of 100 nm as a gate electrode pattern, to form a striped resist mask pattern with pitch of 200 nm and an L/S ratio=1.

This was processed in a reactive ion etching apparatus for 3 min under the conditions of CF₄: flow rate: 20 SCCM, process pressure: 2.0 Pa and RF output: 100 W. Then, it was processed for 10 min under the conditions of Ar: flow rate: 20 SCCM, process pressure: 2.0 Pa and RF output: 100 W. It was furthermore processed for 5 min and 30 sec under the conditions of CF₄: flow rate: 20 SCCM, process pressure: 2.0 Pa, and RF output: 100 W, to provide a structure with a width of 100 nm sequentially comprising a lower insulating film, a gate electrode and an upper insulating film. Here, an array pitch of this structure is 200 nm, and an area between the structures is an opening.

While immersing the substrate comprising this structure and the opening in a 10% aqueous diammonium hydrogen phosphate, a voltage of +10 V was applied to the gate electrode for 5 min using a gold wire as an opposite electrode, to form an oxide film on lateral side of the gate electrode, as lateral insulating film layer. It was immersed into flowing water for 30 min for washing. NPD was deposited on the substrate comprising this structure to a film thickness of 350 nm by vacuum deposition. Here, the opening was filled with NPD to form an intermediate semiconductor portion and a semiconductor portion (B). Herein, a length of the shorter side of the rectangular cross section in the semiconductor portion (B) was 100 nm while a length of the longer side of the rectangular cross section was 600 μm. Then, aluminum as a drain electrode was deposited over the surface to 100 nm by vacuum deposition to prepare an organic thin film transistor.

Thus, twenty organic thin film transistors were prepared and were measured for their transistor properties, and a cutoff frequency was 500 Hz and an ON/OFF ratio was 780 to 820. Thus, it was confirmed again in this example that employing the configuration of the present invention, an organic thin film transistor having a high ON/OFF ratio was manufactured by a convenient process.

### Example 3

An organic thin film transistor was prepared as described in Example 2, except that an exposure pattern by electron-beam drawing was a comb-tooth shape with a line width of 200 nm and a length of the shorter side in the rectangular cross section of the semiconductor portion (B) of 200 nm. Thus, twenty organic thin film transistors were prepared and were measured for their transistor properties, and a cutoff frequency was 400 Hz and an ON/OFF ratio was 680 to 710. Thus, it was confirmed again in this example that employing the configuration of the present invention, an organic thin film transistor having a high ON/OFF ratio was manufactured by a convenient process.

### Comparative Example 2

An organic thin film transistor was prepared as described in Example 2, except that an exposure pattern by electron-beam drawing was a comb-tooth shape with a line width of 300 nm and a length of the shorter side in the rectangular cross section of the semiconductor portion (B) of 300 nm. The organic thin film transistor thus prepared had a cutoff frequency of 200 Hz and an ON/OFF ratio of 1 to 3. Thus, the organic thin film transistor prepared in this comparative example had a low ON/OFF ratio.

### Example 4

There will be described a process for manufacturing an organic thin film transistor according to Embodiment 2 using a shadow mask method. ITO as a source electrode was deposited on a glass substrate to 100 nm by sputtering. A solution of poly(3-hexylthiophene) in xylene was deposited over the substrate to a film thickness of 270 nm as a lower organic semiconductor layer (an intermediate semiconductor portion) by spin coating and the solution was then dried. Over the surface was applied a dispersion prepared by dispersing a silicon wire having a width of 150 nm and a length of 2.5 μm in isopropyl alcohol as a liquid dispersion medium, by dip coating such that the mutually parallel silicon wires are aligned in a given direction, and the dispersion was dried.

AFM observation of the substrate comprising silicon wires showed that the silicon wires are aligned in one direction with an interval of 80 nm. Aluminum as a gate electrode material was deposited over the lower organic semiconductor layer comprising the silicon wires in parallel to a film thickness of 30 nm by vacuum deposition. Then, it was subjected to ultrasonic irradiation while being immersed in methanol, to remove the silicon wires. AFM observation of the substrate after thus removing the silicon wires showed that over the lower organic semiconductor layer, there were cuboid openings with a width of 150 nm in one orientation. Here, the width of 150 nm corresponds to a length of the shorter side in the rectangular cross section of the semiconductor portion (B) while the wire length of 2.5 μm corresponds to a length of the longer side.

A solution of poly(3-hexylthiophene) in xylene was applied over the surface by spin coating to form a film with a thickness of 100 nm and the film was then dried. Here, the openings which the silicon wires removed had occupied was filled with poly(3-hexylthiophene) to form a semiconductor portion (B) while an upper organic semiconductor layer (an intermediate semiconductor portion) was formed. Furthermore, aluminum as a drain electrode was deposited over the surface to 100 nm by vacuum deposition to prepare an organic thin film transistor.

Thus, twenty organic thin film transistors were prepared and were measured for their transistor properties, and a cutoff frequency was 600 Hz and an ON/OFF ratio was 780 to 830. Thus, it was confirmed again in this example that employing the configuration of the present invention, an organic thin film transistor having a high ON/OFF ratio was manufactured by a convenient process.

### Comparative Example 3

Twenty organic thin film transistors were prepared as described in Example 4, except that a length of the silicon wire used in Example 4 (corresponding to a length of the longer side in the rectangular cross section of the semiconductor portion (B)) was 1 μm. For these, transistor properties were measured and a cutoff frequency was 500 MHz and an ON/OFF ratio was considerably varied in a range of 550 to 800. It was thus found that in this comparative example, an organic thin film transistor with unstable element properties was obtained.

1. An organic thin film transistor comprising a source electrode, a first organic semiconductor layer, a gate electrode layer, a second organic semiconductor layer and a drain electrode laminated in sequence,
wherein the gate electrode layer comprises a gate electrode comprising a plurality of wire-shaped conductive materials and a semiconductor portion (A) made of an organic semiconductor material formed between the wire-shaped conductive materials, and
in a projection view of a distribution of the wire-shaped conductive materials in the gate electrode layer to a plane parallel to the source electrode, a distance from any point within the semiconductor portion (A) to the nearest wire-shaped conductive material is 100 nm or less.

2. The organic thin film transistor as claimed in claim 1,
wherein the surfaces of the wire-shaped conductive materials constituting the gate electrode are covered by an insulating film.

3. A process for manufacturing the organic thin film transistor as claimed in claim 1, comprising:
forming the source electrode and the first organic semiconductor layer over the source electrode in sequence;
forming a dispersion in which the wire-shaped conductive materials are dispersed in a liquid dispersion medium;
applying the dispersion to the surface opposite to the surface in the first organic semiconductor layer on which the source electrode is formed;
removing the liquid dispersion medium by heating to form the gate electrode;
depositing an organic semiconductor material over the whole surface opposite to the side of the first organic semiconductor layer in the gate electrode, to form the semiconductor portion (A) and the second organic semiconductor layer; and
forming the drain electrode on the second organic semiconductor layer.

4. An organic thin film transistor comprising a source electrode and a drain electrode facing each other and an intermediate layer sandwiched between the source electrode and the drain electrode,
wherein the intermediate layer comprises a gate electrode layer formed such that the intermediate layer does not contact the source electrode and the drain electrode, and an intermediate semiconductor portion made of an organic semiconductor material formed at least part of the area between the gate electrode layer and the source electrode and at least part of the area between the gate electrode layer and the drain electrode,
the gate electrode layer comprises a gate electrode and a cuboid semiconductor portion (B) penetrating a part of the gate electrode layer in its thickness direction,
the semiconductor portion (B) comprises a rectangular cross section parallel to the plane direction of the gate electrode layer, and the rectangular cross section has a length of shorter side of 20 nm or more and 200 nm or less and a length of longer side of 2 μm or more.

5. The organic thin film transistor as claimed in claim 4,
wherein the surface of the gate electrode is covered by an insulating film.

6. A process for manufacturing the organic thin film transistor as claimed in claim 4, comprising
depositing a plurality of fibrous materials on a deposition-base such that the plurality of fibrous materials are parallel to each other, then depositing a gate electrode material over the whole surface and then removing the plurality of fibrous materials on which the gate electrode material is deposited to form the gate electrode.

7. The process for manufacturing the organic thin film transistor as claimed in claim 4, comprising
forming the gate electrode by lithography.

8. The process for manufacturing the organic thin film transistor as claimed in claim 5, comprising:
depositing a lower insulating film material, a gate electrode material and an upper insulating film material on the source electrode and then forming a structure sequentially comprising a lower insulating film, the gate electrode and an upper insulating film by lithography; and
forming the insulating film over the surface of the gate electrode which does not contact the lower insulating film and the upper insulating film.
